(19) United States
(12) Patent Application Publication
(10) Pub. No.: US 2026/0002978 A1
(43) Pub. Date: Jan. 1, 2026

(54) SIGNAL DETECTION CIRCUIT

(71) Applicant: WNC Corporation, Hsinchu (TW)

(72) Inventor: Shoou-Hann HUANG, Hsinchu (TW)

(21) Appl. No.: 19/245,816

(22) Filed: Jun. 23, 2025

(30) Foreign Application Priority Data
Jun. 28, 2024 (TW) 113124279

(51) Int. Cl. G01R 31/28

(52) U.S. Cl. CPC G01R 31/2839

(57) ABSTRACT

A signal detection circuit is provided. The signal detection circuit includes a first switch, a second switch, an attenuator, a power detector, and a comparator. The first switch receives a test signal and a control signal, and determines whether to output the test signal through a first connection port or a second connection port based on the control signal. The second switch receives an attenuated signal or the test signal output through the second connection port based on the control signal. The attenuator receives the test signal and attenuates it for generating the attenuated signal. The power detector receives the attenuated signal or the test signal output through the second connection port, and outputs an analog signal corresponding to a power of the attenuated signal or the test signal output through the second connection port. The comparator receives the analog signal and outputs the control signal.

### CROSS REFERENCE TO RELATED APPLICATIONS

This application claims priority of Taiwan Patent Application No. 113124279, filed on Jun. 28, 2024, the entirety of which is incorporated by reference herein.

### BACKGROUND OF THE DISCLOSURE

### Field of the Disclosure

The present disclosure relates to signal detection circuits, and in particular it relates to a circuit in which signal power and transient time can be measured.

### Description of the Related Art

In transmitter testing for fourth-generation (4G) and fifth-generation (5G) mobile communications, it is necessary to measure not only the transient time of signal switching between the transmission state and the non-transmission state, but also whether the power of the signal in the non-transmission state complies with specifications.

However, it is challenging, using current technology, to accurately measure the transient time and the signal power in the non-transmission state within the same testing environment in a one-time manner. Therefore, it is necessary to solve the above problem in other ways.

### BRIEF SUMMARY OF THE DISCLOSURE

According to an embodiment of the present disclosure, a signal detection circuit comprises a first switch, an attenuator, a second switch, a power detector and a comparator. The first switch has a first connection port and a second connection port, and is configured to receive a test signal and a control signal. The first switch is determined based on the control signal to output the test signal through the first connection port or the second connection port. The attenuator is configured to couple the first connection port of the first switch to receive the test signal and attenuate it for generating an attenuated signal. The second switch has a third connection port and a fourth connection port, and is configured to receive the attenuated signal and the test signal output through the second connection port, wherein the second switch is determined based on the control signal to receive and output the attenuated signal, or to receive and output the test signal output through the second connection port. The power detector is configured to be coupled to the second switch to receive the attenuated signal or the test signal output through the second connection port, and outputs an analog signal corresponding to a power of the attenuated signal or the test signal output through the second connection port. The comparator is configured to be coupled to the first switch, the second switch and the power detector to receive the analog signal, wherein when the analog signal is higher than a first threshold, the comparator outputs the control signal of a low logic level, but when the analog signal is lower than a second threshold, the comparator outputs the control signal of a high logic level.

The upper limit of the power that the first switch can withstand is not less than a first power, the upper limit of the power that the second switch can withstand is not less than a second power, and the first power is higher than or equal to the second power.

According to another embodiment of the present disclosure, the signal detection circuit further comprises an amplifier. The amplifier is coupled between the second connection port of the first switch and the fourth connection port of the second switch and is configured to amplify the test signal output through the second connection port of the first switch and output the test signal to the second switch.

According to another embodiment of the present disclosure, the signal detection circuit further comprises a RF limiter. The RF limiter is coupled between the amplifier and the second connection port of the first switch and is configured to limit the power of the test signal output through the second connection port of the first switch and output the test signal to the amplifier.

### BRIEF DESCRIPTION OF THE DRAWINGS

The present disclosure can be more fully understood by reading the subsequent detailed description and examples with references made to the accompanying drawings, wherein:

FIG. 1 shows a test environment based on an example of the embodiment of the invention.

FIG. 2 shows a test environment based on an example of the embodiment of the invention.

FIG. 3 shows a test environment based on an example of the embodiment of the invention.

### DETAILED DESCRIPTION OF THE DISCLOSURE

The following detailed description refers to the exemplary embodiments disclosed herein, with instances of the exemplary embodiments illustrated in the drawings. Where possible, the same reference numerals are used in the drawings and description to denote identical or similar parts.

The ordinal terms used in the description and the claims, such as “first” “second” and the like, are intended to indicate the components and do not imply or represent any sequence or order of the components, nor do they indicate any order of the components in terms of their sequence or manufacturing method. These ordinal terms are used solely for the purpose of distinguishing between components with the same or similar names. The terms used in the claims and the description may differ, and accordingly, a “first” component in the description may be referred to as a “second” component in the claims.

The electrical connection or coupling described in the present disclosure may refer to either the direct connection or the indirect connection. The direct connection in which the terminals of two circuit elements are directly connected or connected to each other by a conductor line. The indirect connection in which the terminals of two circuit elements are connected by a switch, a diode, a capacitor, an inductor, a resistor, other suitable elements, or combinations of the foregoing, but not limited to herein.

It should be noted that the following embodiments may be used to replace, reorganize, or mix the features of several different embodiments to accomplish other embodiments without departing from the spirit of the present disclosure. As long as the features of each embodiment do not violate the spirit of the disclosure or conflict with each other, they can be mixed and matched at will.

In order to measure the signal power of a device in the transmission state (TX_ON), a radio frequency (RF) limiter is usually added to the measurement circuit to limit the signal power input to the measurement circuit to avoid damage to the measurement circuit. However, RF limiter can affect the measured transient time. For example, when an RF limiter is not used, the transient time is the time from the maximum power of the signal to the time when the signal is completely turned off. But when an RF limiter is used, the transient time is the time from the signal is limited within the power range allowed by the RF limiter (which is typically less than the maximum power of the signal) to the time when the signal is completely turned off. Therefore, the measured transient time is not the true transient time.

The use of an attenuator also achieves the purpose of limiting the power of the signal input to the measurement circuit in the transmission state. However, the attenuator also affects the power of the signal measured in the non-transmission state. For example, since the attenuator usually requires a large attenuation value to reduce the input signal power to a range that the test equipment can tolerate, it also attenuates the signal power in the non-transmission state, which may result in the signal power in the non-transmission state to be lower than the background noise of the system and produce incorrect measurement results.

In this case, a signal detection circuit is proposed to solve the above problem. The following is an illustration of several embodiments and diagrams.

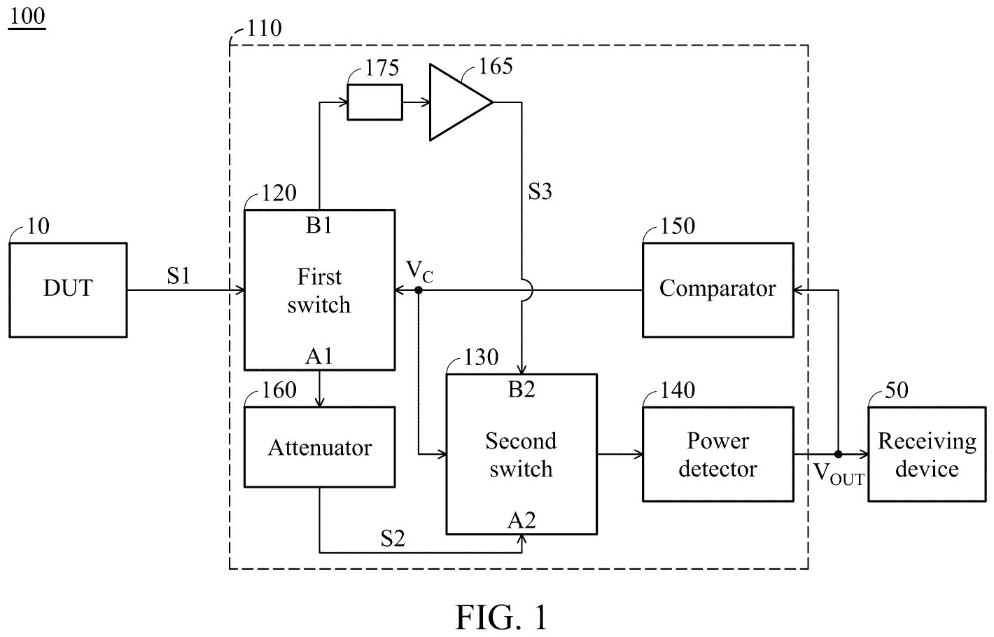

FIG. 1 shows a test environment 100 according to an embodiment of the present disclosure, which may include a device under test (DUT) 10, a signal detection circuit 110, and a receiving device 50. A test signal S1 is transmitted from the DUT 10 to the signal detection circuit 110, and the test signal S1 is converted by the signal detection circuit 110 to output an analog signal V_{OUT} to the receiving device 50. In addition, the receiving device 50 may be an oscilloscope for displaying the analog signal V_{OUT} corresponding to the power level of the signal to be measured, the transient time, or other desired measurement data.

For example, if the receiving device 50 is an oscilloscope, when measuring the transient time, the voltage displayed by the oscilloscope switches from high to low in response to the test signal switching from an ON state (transmission state) to an OFF state (non-transmission state), and the voltage displayed by the oscilloscope switches from low to high in response to the test signal switching from the OFF state to the ON state. Therefore, the time required for the above voltage to switch from high to low or from low to high is the transient time for the test signal to switch from the ON state to the OFF state or from the OFF state to the ON state.

In addition, if the signal power needs to be measured in the non-transmission state, the voltage output to the receiving device 50 (e.g., an oscilloscope) may be compared with the result of the power and voltage calibrated by the signal detection circuit 110 in advance to obtain the power corresponding to the voltage output to the receiving device 50.

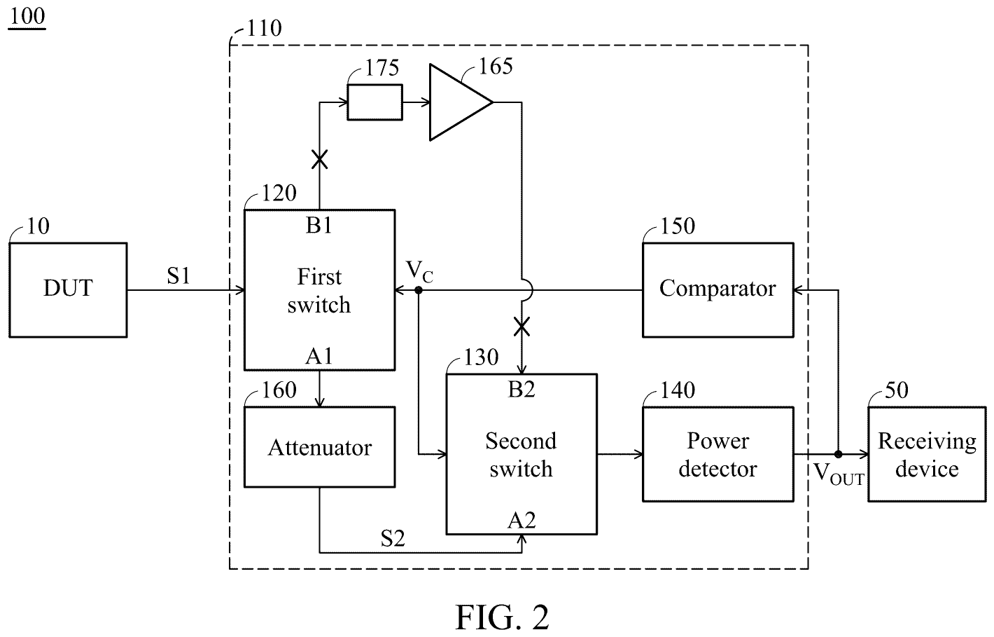

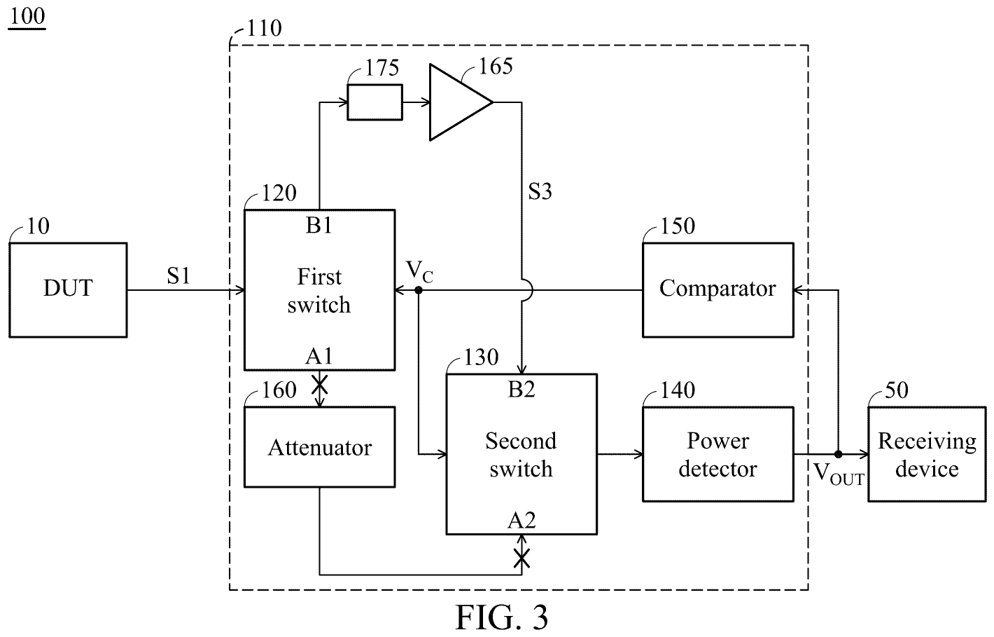

The signal detection circuit 110 may include a first switch 120, a second switch 130, a power detector 140, a comparator 150, an attenuator 160, and an amplifier 165. In some embodiments, the first switch 120 and the second switch 130 may be a single pole double throw (SPDT) switch, wherein the first switch 120 has a power tolerance limit of no less than a first power, and wherein the second switch 130 has a power tolerance limit of no less than a second power. The first power is greater than or equal to the second power. For example, in some embodiments, the first power may be a high power (e.g., 40W) and the second power may be a general power (e.g., 1W). Alternatively, both the first power and the second power may be the high power (e.g., 40W). However, high power components result in higher costs. Thus, the design may be selected in an appropriate configuration based on the power range to be applied. Further, the first switch 120 and the second switch 130 are controlled by a control signal V_{C}. When the voltage level of the control signal V_{C} changes, it causes the first switch 120 and the second switch 130 to switch to a corresponding mode to output or receive signals through a particular connection port. The operation of which is described in detail below in FIG. 2 and FIG. 3.

As shown in FIG. 1, the attenuator 160 is configured to be coupled between a first connection port A1 of the first switch 120 and a third connection port A2 of the second switch 130 for receiving the test signal S1 from the first switch 120 and attenuating it to generate an attenuated signal S2 and output it to the second switch 130.

As shown in FIG. 1, the amplifier 165 is coupled between a second connection port B1 of the first switch 120 and a fourth connection port B2 of the second switch 130 to receive and amplify the test signal S1 in the non-transmission state to generate an amplified signal S3 (i.e., the test signal S1 amplified by the amplifier 165) and output it to the second switch 130. The amplifier 165 may be a variable gain amplifier (VGA) to amplify the test signal S1 with different signal powers. In some embodiments, the signal detection circuit 110 may also exclude the amplifier 165, such that the second connection port B1 of the first switch 120 is directly connected to the fourth connection port B2 of the second switch 130, and the second connection port B1 of the first switch 120 directly outputs the test signal S1 to the fourth connection port B2 of the second switch 130.

In addition, in some embodiments, the signal detection circuit 110 may further include a radio frequency (RF) limiter 175 coupled between the second connection port B1 of the first switch 120 and the amplifier 165 to avoid the damage to the amplifier 165 and/or the second switch 130 due to excessively high power of the received signal.

As shown in FIG. 1, the power detector 140 is configured to receive the attenuated signal S2 received and output by the second switch 130 through the third connection port A2, or is configured to receive the amplified signal S3 received and output by the second switch 130 through the fourth connection port B2 or the test signal S1 output by the second connection port B1 of the first switch 120. The power detector 140 can convert the amplified signal S3 or the test signal S1 output through the second connection port B1 of the first switch 120 into the analog signal V_{OUT} for output to the comparator 150 and the receiving device 50, or convert the attenuated signal S2 into the analog signal V_{OUT} for output to the comparator 150 and the receiving device 50. The signals received and output by the second switch 130 through the fourth connection port B2 (e.g., the amplified signal S3 or the test signal S1 output by the first switch 120) may also be referred to as a detection signal. The comparator 150 may be a Schmitt comparator having a first threshold Vₕ and a second threshold Vₜ. When the analog signal V_{OUT} is greater than the first threshold Vₕ, the comparator 150 outputs the control signal V_{C} with a low logic level (e.g., logic 0) to the first switch 120 and the second switch 130, which causes the signal detection circuit 110 to enter a first mode. In the first mode, the test signal (e.g., attenuated signal S2) is in the transmission state. However, when the analog signal V_{OUT} is lower than the second threshold Vₜ, the comparator 150 outputs the control signal V_{C} with a high logic level (e.g., logic 1) to the first switch 120 and the second switch 130, which causes the signal detection circuit 110 to enter a second mode. In the second mode, the test signal (e.g., the test signal S1 or the amplified signal S3) is in the non-transmission state to measure the signal power in the non-transmission state.

FIG. 2 is an equivalent block diagram of the test environment 100 during the measurement of the transient time according to the embodiment of the present disclosure. Assuming that the control signal V_{C} is at the low logic level (e.g., logic 0) in the initial state, when the first switch 120 receives the test signal S1 from the DUT 10, the first switch 120 would output the test signal S1 to the attenuator 160 through the first connection port A1. The attenuator 160 would attenuate the received test signal S1 and output the attenuated signal S2. Since the control signal V_{C} is at the low logic level, which makes the second switch 130 receive the attenuated signal S2 from the attenuator 160 through the third connection port A2 and output the attenuated signal S2 to the power detector 140.

The power detector 140 converts the received attenuated signal S2 and outputs the analog signal V_{OUT} corresponding to the attenuated signal S2 to the receiving device 50 and the comparator 150. At this time, the test signal S1 is in the transmission state. If the test signal S1 starts to change from the transmission state to the non-transmission state, the corresponding analog signal V_{OUT} would change from a high voltage state (higher than the first threshold Vₕ) to a low voltage state (lower than the second threshold Vₜ). During the change of the voltage of the analog signal V_{OUT} (i.e., transient), the user may measure the transient time at which the test signal S1 is changed from the transmission state to the non-transmission state through the receiving device 50 (e.g., an oscilloscope). Conversely, when the corresponding analog signal V_{OUT} changes from the low voltage state (lower than the second threshold Vₜ) to the high voltage state (higher than the first threshold Vₕ), which means that the test signal S1 changes from the non-transmission state to the transmission state. At this time, the transient time for the test signal S1 to change from the non-transmission state to the transmission state may be measured by the receiving device 50 (e.g., an oscilloscope). The comparator 150 compares the analog signal V_{OUT} with the first threshold Vₕ and the second threshold Vₜ upon receiving the analog signal V_{OUT}. If the analog signal V_{OUT} is higher than the first threshold Vₕ, the comparator 150 will continue to output the control signal V_{C} with the low logic level, such that the signal detection circuit 110 continues to operate in the first mode. If the analog signal V_{OUT} is lower than the second threshold Vₜ, the comparator 150 will output the control signal V_{C} with the high logic level (e.g., logic 1), such that the signal detection circuit 110 switches to the second mode as shown in FIG. 3 to measure the signal power in the non-transmission state.

FIG. 3 is an equivalent block diagram of the test environment 100 for measuring the signal power in the non-transmission state according to the embodiments of the present disclosure. Assuming that the control signal V_{C} is at a high logic level (e.g., logic 1) in the initial state, when the first switch 120 receives the test signal S1 from the DUT 10, the first switch 120 would output the test signal S1 to the amplifier 165 through the second connection port B1. The amplifier 165 amplifies the test signal S1 and outputs the amplified signal S3 to the second switch 130. Since the control signal V_{C} is at the high logic level, the second switch 130 receives the amplified signal S3 from the amplifier 165 through the fourth connection port B2 and outputs the amplified signal S3 to the power detector 140.

The power detector 140 converts the received amplified signal S3 and outputs the analog signal V_{OUT} corresponding to the amplified signal S3 to the receiving device 50 and the comparator 150, while simultaneously measuring the signal power of the amplified signal S3. At this time, the user can view the signal power of the amplified signal S3 in the non-transmission state through the receiving device 50 (e.g., an oscilloscope), and then obtain the signal power of the test signal S1 in the non-transmission state according to the power calibration setting of the signal detection circuit 110. After receiving the analog signal V_{OUT}, the comparator 150 compares the analog signal V_{OUT} with the first threshold Vₕ and the second threshold Vₜ. If the analog signal V_{OUT} is higher than the first threshold Vₕ, the comparator 150 will output the control signal V_{C} with the low logic level, such that the signal detection circuit 110 switches to operate in the first mode. If the analog signal V_{OUT} is lower than the second threshold Vₜ, the comparator 150 will continue to output the control signal V_{C} with the high logic level (e.g., logic 1), such that the signal detection circuit 110 continues to operate in the second mode to measure the signal power in the non-transmission state.

In another embodiment, if the second connection port B1 of the first switch 120 is directly connected to the fourth connection port B2 of the second switch 130, then when the control signal V_{C} is at the high logic level, the first switch 120 will output the test signal S1 directly to the fourth connection port B2 of the second switch 130 through the second connection port B1. Namely, the second switch 130 will receive and output the test signal S1 through the second connection port B1 of the first switch 120. Then, the power detector 140 will convert the test signal S1 output through the second connection port B1 of the first switch 120 and output it to the comparator 150 and the receiving device 50 for the subsequent operations as described above.

As described above, when the second mode is operated to measure the signal power in the non-transmission state, the first switch 120 outputs the test signal S1 to the amplifier 165 through the second connection port B1. However, the second mode is switched to the first mode (i.e., from the non-transmission state to the transmission state), it must wait until the power detector 140 converts the received amplified signal S3 into the analog signal V_{OUT} and outputs the analog signal V_{OUT} to the comparator 150, and the low logic level control signal V_{C} is generated by the comparator 150, then the signal detection circuit 110 may control the first switch 120 to switch to output the test signal S1 through the first connection port A1. Therefore, in the second mode, the test signal S1 (e.g., a high power signal output from the DUT 10) is directly output to the amplifier 165 without being attenuated (e.g., reduced in power). At this time, the amplifier 165 may be damaged if the signal power of the test signal S1 is higher than the upper limit of the power that the amplifier 165 can withstand (e.g., the signal power is higher than 5W). Furthermore, even if the signal power of the test signal S1 is not higher than the upper limit of the power that the amplifier 165 can withstand, the amplifier 165 amplifies and generates the amplified signal S3 and then outputs it to the second switch 130. It is also possible that the power of the amplified signal S3 is higher than the upper limit of the second switch 130, which results in the damage to the second switch 130.

For example, suppose that during the last measurement, the signal detection circuit 110 was operated in the second mode to measure the signal power in the non-transmission state. A high power signal is input to the signal detection circuit 110 (e.g., the test signal S1 is switched from the non-transmission state to the transmission state). At this point, since the control signal V_{C} remains at the high logic level (e.g., logic 1), the above-described high power signal is output through the second connection port B1 of the first switch 120 directly to the amplifier 165 (or in some embodiments, directly to the fourth connection port B2 of the second switch 130).

However, if the power of the above-described high power signal is greater than the upper limit that the amplifier 165 can withstand, the amplifier 165 will be damaged. Further, if the amplifier 165 amplifies the above-described high power signal, it is possible that the above-described high power signal exceeds the upper limit of the power (e.g., the second power) that the second switch 130 can withstand, which causes the second switch 130 to be damaged. In some embodiments, since the second connection port B1 of the first switch 120 is directly connected to the fourth connection port B2 of the second switch 130, the above high power signal is directly output to the second switch 130. However, the second power of the second switch 130 is usually lower than the first power of the first switch 120. Therefore, if the above-described high power signal is directly output to the second switch 130, it may cause damage to the second switch 130.

Thus, the RF limiter 175 can be additionally added between the second connection port B2 of the first switch 120 and the amplifier 165 to limit the signal power input to the amplifier 165 to prevent the amplifier 165 from being damaged due to excessive signal power of the test signal S1. In addition, since the RF limiter 175 only affects the measurement accuracy of the transient time of the signal, and the signal detection circuit 110 only uses the RF limiter 175 when measuring the signal power in the non-transmission state. Therefore, the RF limiter 175 does not adversely affect the test signal S1, and there is no need to remove the RF limiter 175 that has been added to the signal detection circuit 110.

Further, when the signal detection circuit 110 generates the attenuated signal S2 through the attenuator 160 and outputs the attenuated signal S2 to the second switch 130, and then the power detector 140 converts the attenuated signal S2 into an analog signal V_{OUT} corresponding to the attenuated signal S2 and outputs it to the comparator 150. The high logic level control signal VCis generated by the comparator 150 to control the first switch 120 to switch to output the test signal S1 through the second connection port B1 for completing the switching operation from the first mode in FIG. 2 to the second mode in FIG. 3.

As described above, the signal detection circuit proposed herein can be switched between two modes of operation: the non-transmission state and the transmission state. The signal detection circuit can measure the signal power in the non-transmission state when the test signal is in the non-transmission state. Additionally, the signal detection circuit can measure the transient time of the test signal during a brief period when the test signal changes from the non-transmission state to the transmission state or from the transmission state to the non-transmission state. Therefore, the measurement of the transient time yields two results: one is the transient time from the transmission state to the non-transmission state, and the other is the transient time from the non-transmission state to the transmission state. Precisely, the signal detection circuit in the present disclosure uses the power detector to convert the received test signal into the analog signal and output it to the subsequent circuit (e.g., an oscilloscope or other circuits that can utilize the above analog signal). The above analog signal can be transmitted to the comparator to generate the control signal with different logic levels (e.g., logic 1 or logic 0) for controlling the switching of operation modes of the signal detection circuit. Therefore, it will not be affected by the attenuator to cause the signal power in the non-transmission state to be over attenuated, resulting in measurement errors. It will also not be affected by the RF limiter to limit the power, resulting in inaccurate measurement of the transient time.

In addition, the power detector of the signal detection circuit in the present disclosure not only can be connected to the oscilloscope to observe the measurement results of the analog signal, but also it can be connected to other circuits to provide more applications. For example, the signal detection circuit can detect the power state of a transmitted signal in a time-division multiplexing (TMD) communication system, and the user can use the detected power state to carry out other functions, such as a synchronization signal that is synchronized with the cycle of the transmitted signal.

Although the embodiments of the disclosure are described above, it should be understood that the above is presented as an example and not as a limitation. Many of the changes to the above exemplary embodiments of the present disclosure can be implemented without violating the spirit and scope of the disclosure. Therefore, the breadth and scope of the disclosure should not be limited by the above-described examples. More specifically, the scope of the present disclosure should be defined in terms of the scope of the following patent claims and their equivalents. Although the foregoing disclosure is illustrated and depicted by one or more related embodiments, the equivalent variations and modifications will be contemplated by others familiar with the field based on the foregoing specifications and accompanying drawings. In addition, although a particular feature of the present disclosure has been exemplified by one or more related embodiments, the foregoing feature may be combined with one or more other features in such a way that it may be necessary and useful for any known or particular application.

The specialized terminology used herein is for the purpose of describing particular embodiments only and is not intended to be a limitation of the disclosure. Unless the context clearly indicates otherwise, as herein used in the singular, the meanings of one, that, and the above also include the plural. Furthermore, the terms “including,” “comprising,” “having,” or variations thereof, are used either as detailed descriptions or as patent claims. The foregoing terms are intended to include, and are to some extent equivalent to the term “include”. Unless defined differently, all terms used herein (including technical or scientific terms) are to be understood generally by persons of ordinary skill in the art disclosed above. It should be appreciated that terms such as those defined in the dictionaries used by the public should be construed as having the same meaning in the context of the relevant technology. These terms are not to be construed as idealized or overly formal unless expressly defined herein.

What is claimed is:

1. A signal detection circuit, comprising:
a first switch, having a first connection port and a second connection port, and configured to receive a test signal and a control signal, wherein the first switch determines whether to output the test signal through the first connection port or the second connection port based on the control signal;
an attenuator, configured to be coupled to the first connection port of the first switch to receive the test signal and attenuate the test signal for generating an attenuated signal;
a second switch, having a third connection port and a fourth connection port, and configured to receive the attenuated signal and the test signal output through the second connection port, wherein, based on the control signal, the second switch determines whether to receive and output the attenuated signal, or to receive and output the test signal output through the second connection port;
a power detector, configured to be coupled to the second switch to receive the attenuated signal or the test signal output through the second connection port, and output an analog signal corresponding to a power of the attenuated signal or the test signal output through the second connection port; and
a comparator, configured to be coupled to the first switch, the second switch and the power detector to receive the analog signal, wherein when the analog signal is higher than a first threshold, the comparator outputs the control signal with a low logic level, but when the analog signal is lower than a second threshold, the comparator outputs the control signal with a high logic level;
wherein an upper limit of the power that the first switch can withstand is not less than a first power, an upper limit of the power that the second switch can withstand is not less than a second power, and the first power is higher than or equal to the second power.

2. The signal detection circuit as claimed in claim 1, further comprising:
an amplifier, coupled between the second connection port of the first switch and the fourth connection port of the second switch, and configured to amplify the test signal output through the second connection port of the first switch and output the test signal to the second switch.

3. The signal detection circuit as claimed in claim 2, further comprising:
a RF limiter, coupled between the amplifier and the second connection port of the first switch, and configured to limit the power of the test signal output through the second connection port of the first switch and output the test signal to the amplifier.

4. The signal detection circuit as claimed in claim 2, wherein when the control signal is at a low logic level, the test signal is output by the first switch to the attenuator through the first connection port, and the attenuated signal is received by the second switch through the third connection port and is output to the power detector.

5. The signal detection circuit as claimed in claim 4, wherein when the control signal is at a high logic level, the test signal is output by the first switch to the amplifier through the second connection port and is amplified by the amplifier, and an amplified test signal is received by the second switch through the fourth connection port and is output to the power detector.

6. The signal detection circuit as claimed in claim 1, wherein when the control signal is at a low logic level, the test signal is output by the first switch to the attenuator through the first connection port, and the attenuated signal is received by the second switch through the third connection port and is output to the power detector.

7. The signal detection circuit as claimed in claim 6, wherein when the control signal is at a high logic level, the test signal is output by the first switch to the second switch through the second connection port, and the test signal output through the second connection port of the first switch is received by the second switch through the fourth connection port and is output to the power detector.

8. The signal detection circuit as claimed in claim 1, wherein the analog signal is output by the power detector to a receiving device to measure a transient time of the test signal or to obtain a signal power in a non-transmission state.

9. The signal detection circuit as claimed in claim 1, wherein the first switch and the second switch are single pole double throw switches.

10. The signal detection circuit as claimed in claim 2, wherein the amplifier is a variable gain amplifier.
